(19) United States
(12) Patent Application Publication
(10) Pub. No.: US 2006/0046374 A1
(43) Pub. Date: Mar. 2, 2006

(54) Conducting line terminal structure for display device

(75) Inventors: Hsin-Ming Chen, Tainan Hsien (TW); Wen-Yuan Guo, Chiayi Hsien (TW); Jun-Chang Chen, Taichung (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 10/933,120

(22) Filed: Sep. 1, 2004

(51) Int. Cl. H01L 21/8238

(52) U.S. Cl. 438/202

(57) ABSTRACT

A conducting line terminal structure for a display device. The conducting line terminal structure comprises a conducting member and an insulating layer covering a first section of the conductive member. A planarization layer is formed above a second section of the conductive member and overlaps a first section of the insulating layer and a conducting layer conductively couples to a third section of the conductive member.

### BACKGROUND

The invention relates to a display device, and more particularly to a conducting line terminal structure for a display device to electrically connect external driving devices and internal pixel elements.

Liquid crystal displays (LCD) are the most popular flat panel display, having characteristics of low power consumption, thin profile, light weight and requiring low driving voltage. Generally, the LCD device has an array of pixel areas defined by scanning lines and data lines, each pixel area having a pixel electrode and a thin film transistor (TFT) serving as a switching device. In addition, a plurality of bonding pad structures is fabricated on the terminals of the scanning lines and the data lines respectively for electrical connection to external driving ICs by TAB (tape automatic bonding) or FPCB (flexible print circuit board), thus driving the pixel electrodes and providing image signals.

FIG. 1 is a schematic plane view of a conventional LCD device 10. The LCD device 10 comprises a TFT substrate 12, a CF (color filter) substrate 14 and a liquid crystal material filling a space between the substrates 12 and 14. A plurality of bonding pad structures is formed at the peripheral region of the TFT substrate 12 for electrical connection to an external IC board 18 by a signal processing band 16, such as a TAB band or a FPCB.

FIG. 2 is a schematic plane view of the TFT substrate 12 shown in FIG. 1, partially illustrating enlargement of an edge portion 15 thereof. As shown in FIG. 2, the edge portion 15 of the TFT substrate 12 comprises a plurality of conducting lines 20 functioning as scanning lines or data lines for defining an array of pixel elements (not shown). Each conducting line 20 is a plan conducting line and overlies the TFT substrate 12, extending between a display area including pixel elements therein and a bonding area including bonding pad structures therein. Each conducting line 20 in the display area is covered by a planarization layer 22 and exposes a terminal portion 20a thereof not covered by the planarization layer 22 in the bonding area. A step height difference exists between the planarization layer 22 in the display area and the substrate 12 in the bonding area. Such step height extends across the substrate 12, even in the space between adjacent conductive lines, as illustrated in FIG. 4. In addition, a conductive layer 24 is formed overlying and electrically connected to the terminal portion 20a, thus forming a bonding pad 26 for electrical connection to the external IC board 18 by the signal processing band 16, as illustrated in FIG. 1. FIG. 3 illustrates a cross section taken along line 3-3 in FIG. 2, showing a structure in the edge portion 15. The conducting line 20 and the terminal portion 20a thereof are formed by a metal layer 21 and the material thereof can be, for example, aluminum.

Normally, each conductive layer 24 is formed by deposition and patterning of a conductive material such as an indium tin oxide (ITO) and each conductive layer 24 also overlies a portion of the adjacent planarization layer 22. Patterning of the conductive material of the conductive layer 24 can be achieved by conventional photolithography and etching technology.

Due to overlapping of the conductive layer 24 over the planarization layer 22, the conductive lines 20 will not be exposed and potential shorting caused by particle contamination, for example, can be thus prevented.

Nevertheless, during formation of the conductive layers 24, undesired conductive residue 24a of the same conductive material of the conducive layer 24 can sometimes remain on the substrate 12 (e.g., along the edge or step height of the planarization layer 22) due to insufficient exposure during patterning of the conductive material in a boundary between the bonding area and the display area, thus electrically connecting two adjacent bonding pads 26 and causing pin-to-pin shorts of the underlying conductive lines 20.

In FIG. 4, a cross section taken along line 4-4 of FIG. 2 is shown to illustrate the conductive residue 24a causing pin-to-pin shorts of the underlying conducting lines 20 in the related art.

Hence, there is a need for improved conducting line terminal structure for a display device to prevent conductive residue remaining on the substrate, thereby reducing shorts between adjacent conducting line terminal structures.

### SUMMARY

The present invention overcomes the shorting problem in the prior art by avoiding overlap of metallization over the planarization layer during formation of the bonding pads. An insulating layer is provided to separate metallization from the step height formed by the planarization layer. The insulating layer extends below the planarization layer to the metallization layer (e.g., conductive lines on which the bonding pads are formed), but not in between adjacent metallized structures. During the metallization process for forming the conductive lines and/or bonding pads, the metal layer extends to overlap the insulating layer, but not the planarization layer or step height. Consequently, this significantly reduces the possibility of shorting of adjacent conducting lines along the edge (step height) of the planarization layer. A conductive layer may be provided below the insulating layer, which may be part of the conductive line or other conductive structures, or structurally coupled to conductive lines and/or other conductive structures overlapping the insulating layer, through via provided in the insulating layer.

Accordingly, in an embodiment of the invention, a conducting line terminal structure for a display device is provided. The conducting line terminal comprises a conducting member and an insulating layer covering a first section of the conductive member. A planarization layer is formed above a second section of the conductive member and overlaps a first section of the insulating layer and a conducting layer conductively couples to a third section of the conductive member.

An embodiment of the invention also provides a method of forming the conducting line terminal structure. In the method, an array of adjacent conducting members is formed. An insulating layer is formed to cover a first section of each conductive member. A planarization layer is formed above a second section of the array of conductive members and overlaps a first section of the insulating layer, the planarization layer spanning between adjacent conductive members. A conducting layer conductively is formed to couple third section of each conductive member and away from the second section overlapped by the planarization layer.

An embodiment of the invention also provides a display device. The display device comprises a display panel and a controller coupled to and driving the display panel to render an image in accordance with an input. The display panel comprises an array substrate with a conducting member and an insulating layer covering a first section of the conductive member. A planarization layer is formed above a second section of the conductive member and overlaps a first section of the insulating layer and a conducting layer conductively couples to a third section of the conductive member.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic plane view showing a conventional LCD device;

FIG. 2 is a schematic plane view partially illustrating the TFT substrate 12 in FIG. 1;

FIG. 3 is a cross section along line 3-3 of FIG. 2 to illustrate a conductive structure in the boundary between a bonding area and a display area;

FIG. 4 is a cross section along line 4-4 of FIG. 2 to illustrate a conductive residue left in the boundary between a bonding area and a display area;

FIG. 5 is a schematic plane view partially illustrating an array substrate for a display device according to an embodiment of the invention;

FIGS. 6a˜6d are cross sections along line 5-5 of FIG. 4 respectively illustrating fabrication steps forming conducting line terminal structures for a display device according to an embodiment of the invention;

FIG. 7 is a cross section along line 7-7 of FIG. 4 to illustrate a structure without conductive residue left in the boundary between a bonding area and a display area;

FIG. 8 is a schematic plane view of a display device according to an embodiment of the invention, incorporating the array substrate in FIG. 5;

FIG. 9 is a schematic view illustrating a display device according to an embodiment of the present invention, incorporating a controller; and

FIG. 10 is a schematic diagram illustrating an electronic device according to an embodiment of the invention, incorporating the display device in FIG. 9.

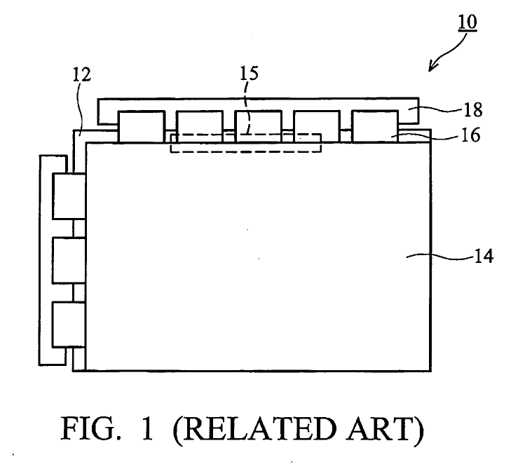

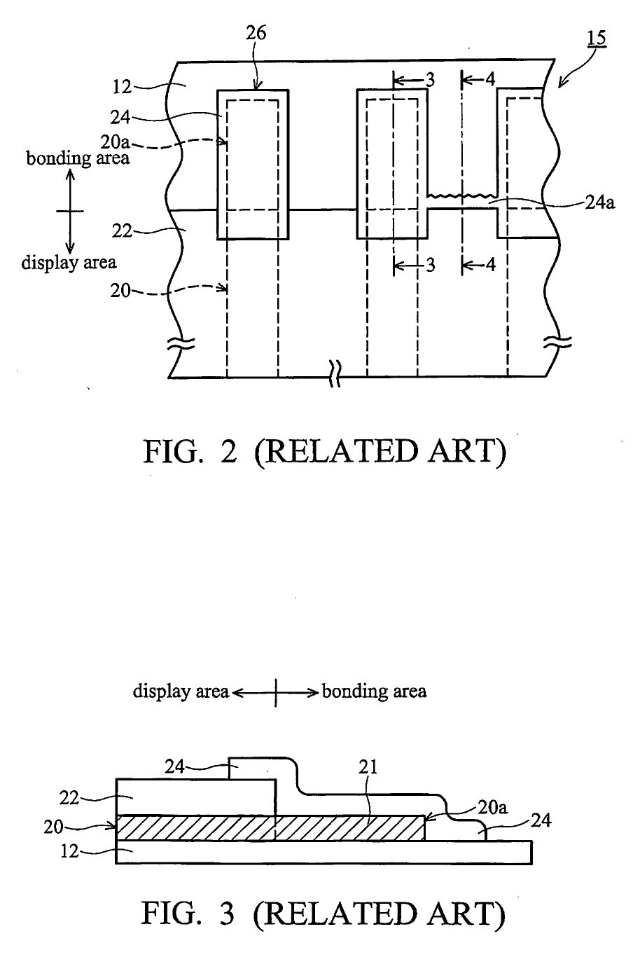

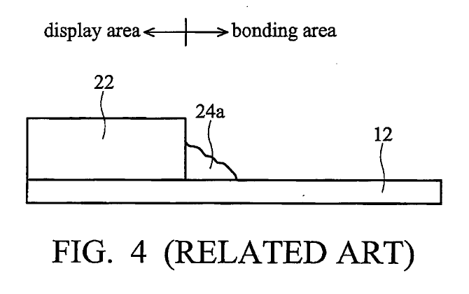

### DETAILED DESCRIPTION

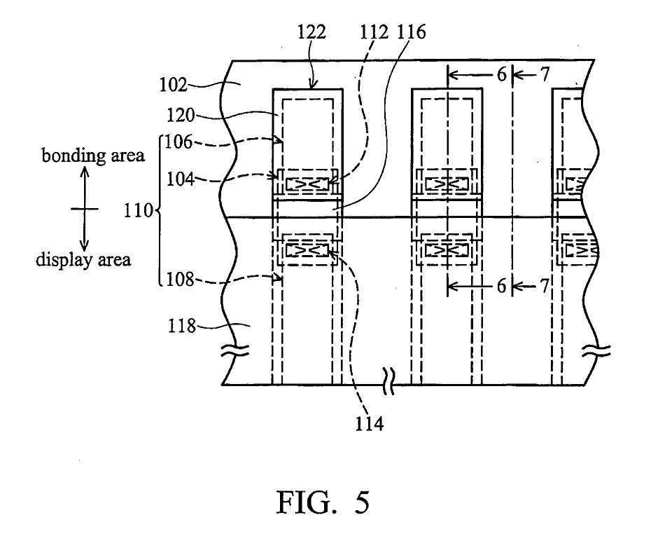

In FIG. 5, a schematic plane view of an array substrate 102 for a display device according to an embodiment of the invention is illustrated, partially showing an edge portion thereof.

As shown in FIG. 5, the edge portion of the array substrate 102 comprises a plurality of conducting lines 110 functioning as scanning lines or data lines defining an array of pixel elements (not shown). Each conducting line 110 overlies the array substrate 102, extending between a display area, forming pixel elements therein and a bonding area, forming bonding pads therein.

Herein, each conducting line 110 has a structure comprising three independent conductive members 104, 106 and 108. Conductive member 104 underlies conductive members 106 and 108 and electrically connects thereto through the contact holes 112 and 114 formed in an insulating layer 116, respectively. The insulating layer 116 overlies the conductive member 106 and between the conductive members 104 and 108, providing insulation thereof. The conducting lines 110 can electrically connect external driving devices and internal pixel elements (not shown) formed in the display area.

Herein, a portion of the insulating segment 116, a portion of the underlying conductive member 104, and the conductive member 108 within the display area are covered by a planarization layer 118. The conductive member 106 formed within the bonding area, not covered by the planarization layer 118, is exposed as a terminal portion of each conducting line 110. In addition, a conductive layer 120 is formed overlying and electrically connected to the conductive member 106, thus forming a bonding pad 122.

Due to passivation of the planarization layer 118 and the insulating layer 116 to the conductive members 108 and the underlying conductive member 104 of the structure of the conducting lines 110 shown in FIG. 5, conductive residue in the boundary between the bonding area and the display area is prevented.

Fabrication of the conducting line 110 along line 6-6 in FIG. 5 is illustrated by cross sections 5a-5d for better understanding.

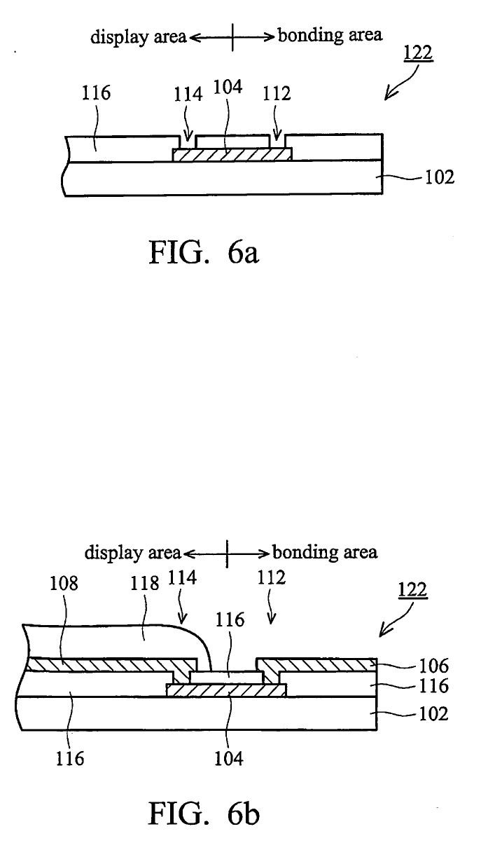

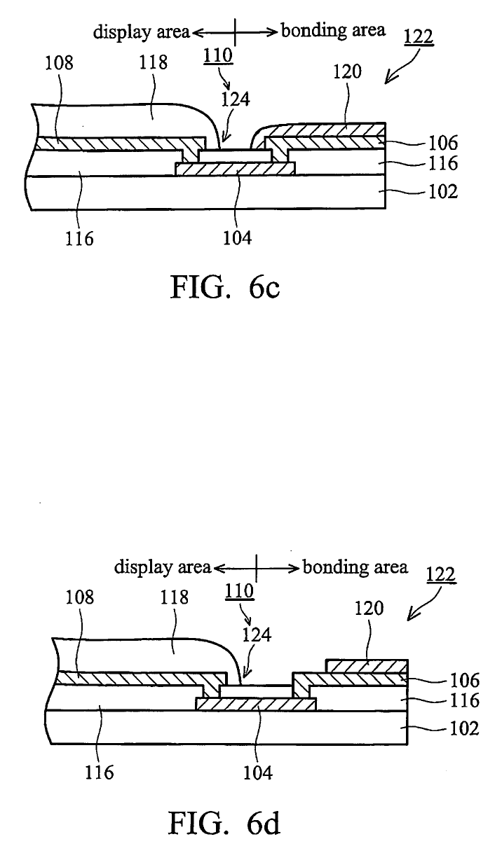

In FIG. 6a, an array substrate 102, such as a TFT substrate for a liquid crystal display (LCD) device, is first provided. Next, a first conductive layer of material such as aluminum (Al), chromium (Cr) or molybdenum (Mo) is blanketly formed over the array substrate 102 and then patterned to form a conductive member 104 over a portion of the array substrate 102. The conductive member 104 overlies the substrate in the display area and also in the bonding area.

Next, an insulating layer 116 is formed over the array substrate 102 to cover the array substrate 102 and the conductive member 104. The insulating layer 116 can be, for example, an oxide layer. In the insulating layer 116, contact holes 112 and 114 are then respectively formed in relative position above both ends of the conductive member 104 by patterning the insulating layer 116.

In FIG. 6b, a second conductive layer of material such as aluminum (Al), chromium (Cr) or molybdenum (Mo) is then formed over the insulating layer 116 and fills the contact holes 112 and 114, thus electrically connecting the conductive member 104 to other sequentially formed devices. The second conductive layer is then patterned to leave conductive members 106 and 108 over the insulating layer 116 in the bonding area and in the display area, respectively.

Next, a planarization layer 118 is formed over the array substrate 102 and patterned to cover the conductive member 108 within the display area and a portion of the adjacent insulating layer 116, exposing the conductive member 106 in the bonding area.

In FIG. 6c, a conductive layer 120 of transparent conductive material such as indium tin oxide (ITO), indium zinc oxide (IZO), or the like is blanketly formed over the array substrate 102 and then patterned to leave a conductive layer 120 overlying the conductive member 106 in the bonding area, thus forming a bonding pad 122 for external driving device attachment. In FIG. 6d, the conductive layer 120 can be patterned to partially cover the conductive member 106 in the bonding area, thus forming a bonding pad 122 for external driving device attachment.

Herein, as shown in FIGS. 6c and 6d, a novel structure of a conducting line 110 of this embodiment is illustrated. The conducting line 110 comprises the conductive members 106 and 108 overlying the insulating layer 116, and the underlying conductive member 104 embedded in the insulating layer 116. The conductive members (i.e. the conductive members 104, 106 and 108) of the three-piece conducting line 110 near the boundary of the display area and bonding area is are passivated by the insulating layer 116 and the passivation layer 118.

In alternate embodiments (not shown), the conductive member 104 may be extended to form, or may be part of, the conductive member 108 and/or conductive member 106. In fact, a single, unitary conductive member (e.g., in the form of a conductive line) may comprise members 104, 106 and 108. Further, it is not necessary to have conductive members 106 and 108 be formed in the same layering process. Also, it is not necessarily to have the insulating layer 116 under the conductive member 106 and/or conductive member 108. There may be one or more intermediate layers between the planarization layer and the conductive member 108. These and other variations are well within the scope and spirit of the present invention.

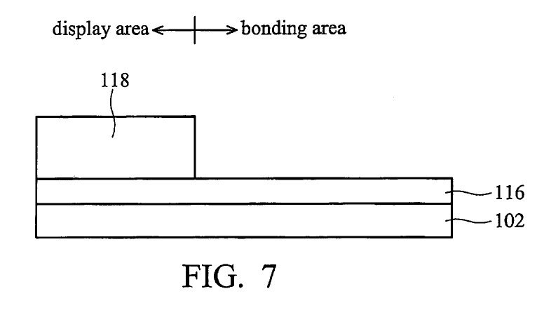

As shown in FIG. 5, the array substrate 102 with the bonding pads 122 and the conducting lines 110 formed thereon can be applied to an LCD (liquid crystal display) device or an OLED (organic electro-luminescent display) device. The bonding pad 122 is formed on the terminal of each conducting line 110, which may functioning as a scanning line or a data line. Herein, the conductive layer 120 covers only the conductive member 106 in the bonding area and does not cover the planarization layer 118 or extend between adjacent conductive members 106 as illustrated in FIG. 7, thus undesired conductive residue of the same conductive material of the conducive layer 120 is no more remain on the substrate 102 in a boundary between the bonding area and the display area, thus preventing pin-to-pin shorts of the adjacent conductive lines 110. In FIG. 7, a cross section taken along the line 7-7 of FIG. 5 which illustrating a structure without conductive residue left in the boundary between a bonding area and a display area is thus formed is shown. (Alternatively, the insulating layer 116 could extend across the substrate 102, covering regions between adjacent conducting lines.)

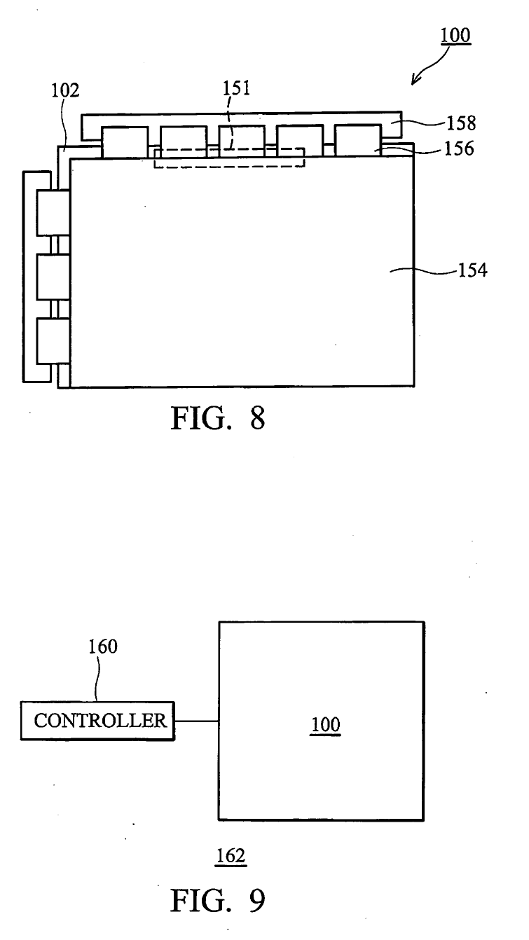

In addition, as shown in FIG. 8, the array substrate 102 including an edge portion 151 illustrated in FIG. 5 can be incorporated in a display panel 100. The display panel further comprises an opposing substrate 154 such as a CF (color filter) substrate of a LCD display. A plurality of bonding pads (not shown) is formed at the peripheral region of the array substrate 102 for electrical connection to an external IC board 158 by a signal processing band 156, such as a TAB band or a FPCB.

Moreover, the display panel 100 shown in FIG. 8 can be coupled to a controller 160 disposed on IC Board 158, as shown in FIG. 8, forming a display device 162. The controller 160 can comprise source and gate driving circuits (not shown), controlling the display panel 100 for operation of the display device 162.

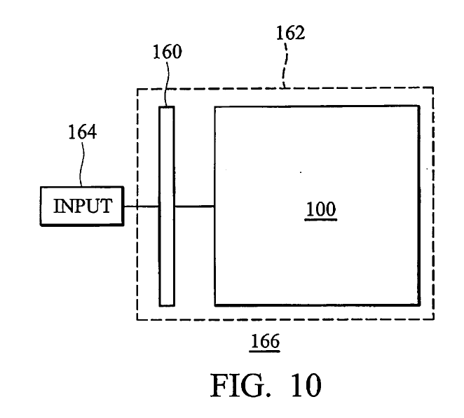

FIG. 10 is a schematic diagram illustrating an electronic device incorporating the display device 162 shown in FIG. 9. An input device 164 is coupled to the controller 160 of the display device 162 shown in FIG. 9 to form an electronic device 166. The input device 164 can include a processor or the like to input data to the controller 160 to render an image. The electronic device 166 may be a portable device such as a PDA, notebook computer, tablet computer, cellular phone, or a display monitor device, or a non-portable device such as a desktop computer.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A conducting line terminal structure, comprising:
a conducting member;
an insulating layer covering a first section of the conductive member;
a planarization layer above a second section of the conductive member and overlapping a first section of the insulating layer; and
a conducting layer conductively coupled to a third section of the conductive member.

2. The conducting line terminal structure as in claim 1, wherein at least two of the first, second and third sections of the conductive member are at different layer levels.

3. The conducting line terminal structure as in claim 2, wherein said at least two of the first, second and third sections of the conductive member are coupled through a via provided in the insulating layer.

4. The conducting line terminal structure as in claim 1, wherein the conducting layer extends to overlapping a second section of the insulating layer but away from the second section overlapped by the planarization layer.

5. The conducting line terminal structure as in claim 1, wherein the conductive layer above the third section of the conductive member further comprises a bond pad layer.

6. The conducting line terminal structure as in claim 1, wherein the first, second and third sections of the conductive member and the conducting layer comprises aluminum (Al), chromium (Cr) or Molybdenum (Mo).

7. The conducting line terminal structure as in claim 5, wherein the bond pad layer comprises indium tin oxide (ITO) or indium zinc oxide (IZO).

8. The conducting line terminal structure as in claim 1, wherein the first, second and third sections of the conductive member are substantially arranged in a line.

9. The conducting line terminal structure as in claim 1, wherein the first, second and third sections of the conductive member constitute a data line or a scan line.

10. A method of forming conducting line terminal structure, comprising the steps of:
forming an array of adjacent conducting members;
forming an insulating layer covering a first section of each conductive member;
forming a planarization layer above a second section of the array of conductive members and overlapping a first section of the insulating layer, the planarization layer spanning between adjacent conductive members; and
forming a conducting layer conductively coupled to a third section of each conductive member and away from the second section overlapped by the planarization layer.

11. A display device, comprising:
a display panel; and
a controller coupled to and driving the display panel to render an image in accordance with an input, wherein the display panel comprises an array substrate, and the array substrate comprises the conducting line terminal structure of claim 1.

12. The display device as claimed in claim 11, wherein the display panel is a liquid crystal display (LCD) panel.

13. The display device as claimed in claim 11, wherein the display panel is an organic electro-luminescent display (OLED) panel.
